(19) United States
(12) Patent Application Publication
(10) Pub. No.: US 2010/0108263 A1
(43) Pub. Date: May 6, 2010

(54) EXTENDED CHAMBER LINER FOR IMPROVED MEAN TIME BETWEEN CLEANINGS OF PROCESS CHAMBERS

(75) Inventors: HOAN Hai NGUYEN, Milpitas, CA (US); Michael D. Willwerth, Campbell, CA (US)

Correspondence Address: MOSER IP LAW GROUP / APPLIED MATERIALS, INC., 1030 BROAD STREET, 2ND FLOOR, SHREWSBURY, NJ, 07702, US

(73) Assignee: APPLIED MATERIALS, INC., Santa Clara, CA (US)

(21) Appl. No.: 12/261,976

(22) Filed: Oct. 30, 2008

(51) Int. Cl. H01L 21/306

(52) U.S. Cl. 156/345.33

(57) ABSTRACT

Embodiments of liners for semiconductor process chambers are provided herein. In some embodiments, a liner for a semiconductor process chamber includes a first portion configured to line at least a portion of an inner volume of the semiconductor process chamber and a second portion configured to line at least a portion of a pump port of the semiconductor process chamber. In some embodiments, the first portion and the second portion are coupled together. In some embodiments, the first portion and the second portion of the liner may be fabricated a single piece. In some embodiments, the liner may be disposed in a process chamber having an inner volume and a pump port fluidly coupled to the inner volume.

### FIELD

Embodiments of the present invention generally relate to semiconductor processing equipment.

### BACKGROUND

The fabrication of semiconductor devices can undesirably result in the deposition of byproducts on the components of a semiconductor process chamber. For example, in an etching process, wafer byproducts can collect on the walls of the process chamber. Typically, a chamber liner is used to line the walls of the process chamber where byproducts may collect, thus preventing byproducts from directly depositing on the chamber wall. When the liner becomes excessively covered with byproducts, the liner may be cleaned in place, removed and cleaned, or simply replaced.

Unfortunately, in some chamber configurations, byproducts may also undesirably deposit on other surface such as on the walls of the pump port and/or pumping mechanism. As such, this undesired deposition of byproducts may result in a reduction of performance in the pumping mechanism, and thus a reduction in the mean time between chamber cleaning (MTBC).

Thus, there is a need in the art for improved chamber lining systems.

### SUMMARY

Embodiments of liners for semiconductor process chambers are provided herein. In some embodiments, a liner for a semiconductor process chamber includes a first portion configured to line at least a portion of an inner volume of the semiconductor process chamber and a second portion configured to line at least a portion of a pump port of the semiconductor process chamber. In some embodiments, the first portion and the second portion are coupled together. In some embodiments, the first portion and the second portion of the liner may be fabricated a single piece.

In some embodiments, an apparatus for semiconductor processing includes a process chamber having an inner volume. A pump port is fluidly coupled to the inner volume and a liner is disposed within the process chamber. The liner covers at least a portion of the inner volume and at least a portion of the pump port.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a schematic side view of an etch reactor having a liner in accordance with some embodiments of the invention.

FIG. 2 depicts a partial schematic side view of a liner in accordance with some embodiments of the invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of liners for semiconductor process chambers are provided herein. In some embodiments, the liner may comprise a first portion configured to line at least a portion of an inner volume of the process chamber and a second portion configured to line at least a portion of a pump port of the process chamber. The inventive liner advantageously limits deposition of unwanted materials on the surfaces of the pump port, facilitating a reduction in the mean time between cleaning (MTBC) of the chamber, and improving equipment uptime and process throughput.

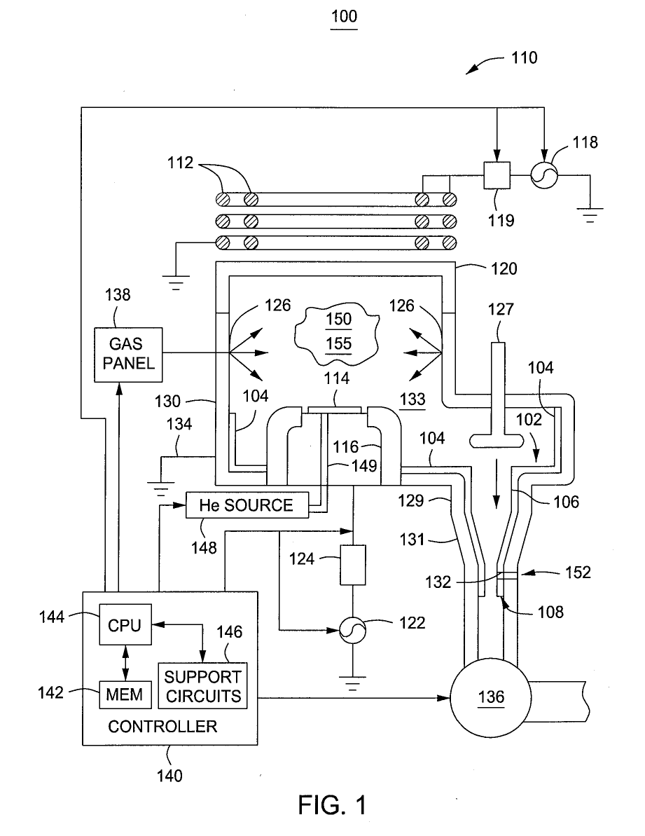

The inventive liners disclosed herein may be utilized in any suitable processing equipment having a pump port and wherein processing byproducts are undesirably deposited on portions of the pump port. For example, FIG. 1 depicts a schematic diagram of an exemplary etch reactor 100 having an inventive liner 102 disposed therein. The reactor 100 may be utilized alone or, more typically, as a processing module of an integrated semiconductor substrate processing system, or cluster tool (not shown), such as a CENTURA® integrated semiconductor wafer processing system, available from Applied Materials, Inc. of Santa Clara, Calif. Examples of suitable etch reactors 100 include the DPS® line of semiconductor equipment (such as the DPS®, DPS® II, DPS® AE, DPS® G3 poly etcher, or the like), the ADVANTEDGE™ line of semiconductor equipment (such as the AdvantEdge, AdvantEdge G3), or other semiconductor equipment (such as ENABLER®, E-MAX®, or like equipment), also available from Applied Materials, Inc. The above listing of semiconductor equipment is illustrative only, and other etch reactors, and non-etch equipment (such as CVD reactors, or other semiconductor processing equipment) may be utilized with the inventive liners described herein.

The reactor 100 generally comprises a process chamber 110 having a conductive body (wall) 130 and ceiling 120 enclosing an inner volume 133. A wafer support pedestal 116 is disposed with the inner volume 133. The chamber 110 includes a pump port 129 disposed at the base of the conductive body 130 and having a throttle valve 127 for controlling the exhaust of process gases from the chamber 110. The liner 102 is disposed in at least a portion of the inner volume 133 and at least a portion of the pump port 129 and can be utilized to limit the deposition of process gases or byproducts therefrom on the portions of the inner volume 133 and pump port covered by the liner 102. The reactor 100 further includes a controller 140 which may be utilized to control operation of the chamber 110 and components coupled thereto.

The support pedestal (cathode) 116 may be coupled, through a first matching network 124, to a biasing power source 122. The biasing source 122 generally is a source of up to 500 W at a frequency of approximately 13.56 MHz that is capable of producing either continuous or pulsed power. In other embodiments, the source 122 may be a DC or pulsed DC source. The chamber 110 is supplied with a substantially flat dielectric ceiling 120. Other modifications of the chamber 110 may have other types of ceilings such as, for example, a dome-shaped ceiling or other shapes. At least one inductive coil antenna 112 is disposed above the ceiling 120 (two co-axial antennas 112 are shown in FIG. 1). Each antenna 112 is coupled, through a second matching network 119, to a plasma power source 118. The plasma source 118 typically is capable of producing up to 4000 W at a tunable frequency in a range from 50 kHz to 13.56 MHz. Typically, the wall 130 may be coupled to an electrical ground 134.

During a typical operation, a semiconductor substrate, or wafer 114 may be placed on the pedestal 116 and process gases are supplied from a gas panel 138 through entry ports 126 and form a gaseous mixture 150. The gaseous mixture 150 is ignited into a plasma 155 in the chamber 110 by applying power from the plasma source 118 to the antenna 112. Optionally, power from the bias source 122 may be also provided to the cathode 116. The pressure within the interior of the chamber 110 is controlled using the throttle valve 127 and a vacuum pump 136. The vacuum pump is fluidly coupled to the inner volume 133 via the pump port 129. The throttle valve 127 controls the pressure by controlling the size of an opening in the upper portion of the pump port 129. The temperature of the chamber wall 130 is controlled using liquid-containing conduits (not shown) that run through the wall 130.

As depicted in FIG. 1, the liner 102 is disposed in at least a portion of the inner volume 133 of the process chamber 110, and is configured to line at least a portion of the pump port 129. The liner 102 may comprise a first portion 104 disposed in the inner volume 133 and a second portion 106 disposed in the pump port 129. The second portion 106 of the liner 102 may extend any distance into the pump port 129 as desired or as practical depending upon the configuration of the pump port 129 and components coupled thereto, such as the vacuum pump 136, throttle valve 127, or the like. In some embodiments, an end 108 of the second portion 106 of the liner 102 may be disposed up to about 0.25 inches within an adjacent component disposed within the pump port, or a conduit leading therefrom, such as, for example, a movable valve component (e.g., a gate valve or the like).

The liner 102 may comprise one or more of anodized aluminum, aluminum coated with yttrium, or the like. The first and second portions 104, 106 may comprise the same or different materials. The liner 102 may be utilized with any suitable semiconductor processes that may be performed in the process chamber 110. However, the liner 102 may also be utilized in other process chambers in connection with other processes. In one illustrative embodiment, the liner 102 is used with a metal etch process resulting in the deposition of polymeric process byproducts thereupon.

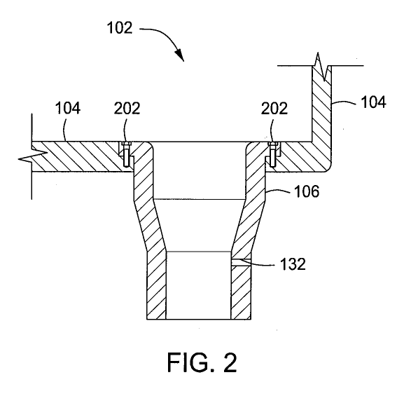

The first portion 104 and the second portion 106 of the liner 102 may be placed in close alignment, coupled together, or formed of single piece construction. In some embodiments, the first portion 104 and the second portion 106 are individual pieces that are coupled together to form a continuous liner surface from at least a portion of the inner volume 133 to at least a portion of the pump port 129. The first portion 104 and the second portion 106 may be coupled by one or more of bolting, welding, press fit, or the like. For example, as depicted in FIG. 2, the first portion 104 and the second portion 106 may be bolted together by a plurality of bolts 202. Alternatively, in some embodiments, the first portion 104 and the second portion 106 may be one continuous piece, and having no seam or joint. A continuous liner of this type may be formed by any suitable method, for example, spinning, casting or forming, or the like.

Returning to FIG. 1, the first portion 104 may be disposed in the inner volume 133 of process chamber 110. The first portion 104 may cover any portion of the interior of the process chamber. In some embodiments. The first portion 104 covers a lower portion of the chamber wall from about the surface of the support pedestal 116 to the base of the chamber 110. Other configurations of the first portion 104 are possible, for example, the first portion 104 may cover the walls 130 up to and/or including the ceiling 120 forming the inner volume 133, other portions of the walls 130, or the like. In some embodiments, the first portion 104 may have a textured surface to facilitate improved collection of byproducts, contaminants, or like. For example, the textured surface may facilitate layer formation of byproducts, or the like, thus limiting flaking onto the substrate 114 as the first portion 104 collects additional materials upon repeated chamber use. The textured surface may be formed by methods such as blasting, machining, laser or e-beam etching, or the like. In some embodiments, the second portion 106 may also have a textured surface as described above.

In some embodiments, the second portion 106 may interface with the first portion 104 proximate an interface between the process chamber 110 and the pump port 129 to facilitate ease of construction, installation, or the like. Other configurations are possible and may depend on, for example, the shape of the pump port 129 and/or the type of valve used in the pump port 129. The second portion 106 may have a length at least sufficient to cover any non-vertical surfaces of the pump port 129 (and conduits coupled thereto) that may provide surface upon which exhaust polymers may be more prone to deposit. For example, the pump port 129 may include a region 131 that necks down in diameter and provides a surface upon which exhaust polymers conventionally deposit without the benefit of the second portion 106 of the liner 102.

In some embodiments, the second portion 106 may include an opening 132 disposed therein configured to interface with an auxiliary exhaust outlet 152 of the pump port 129 utilized, for example, to couple a roughing pump to the process chamber to quickly pump out the process chamber prior to controlling the pressure therein with the vacuum pump 136.

Returning to the reactor 100, the temperature of the wafer 114 may be controlled by stabilizing a temperature of the support pedestal 116. In one embodiment, the helium gas from a gas source 148 is provided via a gas conduit 149 to channels formed by the back of the wafer 114 and grooves (not shown) in the pedestal surface. The helium gas is used to facilitate heat transfer between the pedestal 116 and the wafer 114. During the processing, the pedestal 116 may be heated by a resistive heater (not shown) within the pedestal to a steady state temperature and then the helium gas facilitates uniform heating of the wafer 114. Using such thermal control, the wafer 114 may be maintained at a temperature of between 0 and 500 degrees Celsius.

The controller 140 comprises a central processing unit (CPU) 144, a memory 142, and support circuits 146 for the CPU 144 and facilitates control of the components of the etch process chamber 110 and, as such, of etch processes, such as discussed herein. The controller 140 may be one of any form of general-purpose computer processor that can be used in an industrial setting for controlling various chambers and sub-processors. The memory, or computer-readable medium, 142 of the CPU 144 may be one or more of readily available memory such as random access memory (RAM), read only memory (ROM), floppy disk, hard disk, or any other form of digital storage, local or remote. The support circuits 146 are coupled to the CPU 144 for supporting the processor in a conventional manner. These circuits include cache, power supplies, clock circuits, input/output circuitry and subsystems, and the like. The inventive method may be stored in the memory 142 as software routine and may be executed or invoked in the manner described above. The software routine may also be stored and/or executed by a second CPU (not shown) that is remotely located from the hardware being controlled by the CPU 144.

During operation, the liner 102 may become covered by byproducts of a semiconductor process. The byproducts may include materials from the substrate 114 that are etched, process gases and/or process gas byproducts from a semiconductor process, or contaminants that existed in the chamber 110 prior to processing. The byproducts may deposit on the first portion 104 and the second portion 106 of the liner 102, covering at least some of the surface of the first and second portions. In some embodiments, the byproducts may form a layer covering the surfaces of the first and second portions. The contamination on the liner 102 may reach a critical level, for example, as determined by the number of wafers processes, the quality of the most recent wafer processed, visual inspection, or other suitable means of determining the level of contamination on the liner 102. When the critical level is reached, the liner 102 may be replaced, cleaned, or removed and cleaned.

In some embodiments, the liner 102 may be cleaned in-situ, for example, utilizing a plasma formed from a suitable cleaning gas. Upon completion of the in-situ clean, the process chamber 110 may resume processing semiconductor substrates. Alternatively, the liner 102 may be removed and cleaned ex-situ. For example, ex-situ cleaning may include dipping the liner 102 in a chemical bath, which may comprise acids such as hydrofluoric acid (HF), hydrochloric acid (HCL), or the like.

Liners for semiconductor process chambers have been provided herein. The inventive liners may comprise a first portion configured to line at least a portion of an inner volume of the process chamber and a second portion configured to line at least a portion of a pump port of process chamber. The inventive liners advantageously limit deposition of unwanted materials on the surfaces of the pump port, and further, reduce the mean times between cleaning, thus improving equipment uptime and process throughput.

While the foregoing is directed to embodiments of the present invention, other and further embodiments of the invention may be devised without departing from the basic scope thereof, and the scope thereof is determined by the claims that follow.

1. A liner for a semiconductor process chamber, comprising:
a first portion configured to line at least a portion of an inner volume of a semiconductor process chamber; and
a second portion configured to line at least a portion of a pump port of the semiconductor process chamber.

2. The liner of claim 1, wherein the first and second portions are coupled together.

3. The liner of claim 2, wherein the first and second portions are coupled together by at least one of bolting, welding, or press fit.

4. The liner of claim 1, wherein the first portion and the second portion of the liner are integrally formed.

5. The liner of claim 1, wherein the first portion and/or the second portion comprises at least one of anodized aluminum or yttrium-coated aluminum.

6. The liner of claim 1, wherein the second portion is configured to line the pump port up to about 0.25 inches above a valve disposed within the pump port.

7. The liner of claim 1, wherein the second portion further comprises an opening disposed therein configured to interface with an auxiliary exhaust outlet.

8. An apparatus for semiconductor processing, comprising:
a process chamber having an inner volume;
a pump port fluidly coupled to the inner volume; and
a liner disposed within the process chamber and covering at least a portion of the inner volume and at least a portion of the pump port.

9. The apparatus of claim 8, wherein the liner further comprises:
a first portion lining at least a portion of the inner volume; and
a second portion lining at least a portion of the pump port.

10. The apparatus of claim 8, wherein the process chamber further comprises a throttle valve disposed in the pump port.

11. The apparatus of claim 10, wherein the second portion lines the pump port up to about 0.25 inches from a closed position of the throttle valve.

12. The apparatus of claim 8, wherein the first and second portions are coupled together.

13. The apparatus of claim 8, wherein the first and second portions are coupled together by at least one of bolting, welding, or press fit.

14. The apparatus of claim 8, wherein the liner is formed of one-piece construction.

15. The apparatus of claim 8, wherein the first portion and/or the second portion comprise at least one of anodized aluminum or yttrium-coated aluminum.

16. The apparatus of claim 8, wherein the pump port further comprises an auxiliary exhaust outlet disposed therein, and wherein the second portion further comprises an opening for interfacing with the auxiliary exhaust outlet.

17. The apparatus of claim 8, wherein the process chamber further comprises a substrate support and wherein the first portion lines the inner volume of the process chamber below the substrate support.
